(19) United States
(12) Patent Application Publication
(10) Pub. No.: US 2026/0282708 A1
(43) Pub. Date: Sep. 17, 2026

(54) DISPLAY DEVICE, ELECTRONIC DEVICE, AND METHOD FOR MANUFACTURING DISPLAY DEVICE

(71) Applicant: Samsung Display Co., Ltd., Yongin-si (KR)

(72) Inventors: Sung Hwan YOUN, Yongin-si (KR); Ki Hyun KIM, Yongin-si (KR)

(73) Assignee: Samsung Display Co., Ltd., Yongin-si (KR)

(21) Appl. No.: 19/337,254

(22) Filed: Sep. 23, 2025

(30) Foreign Application Priority Data
Mar. 12, 2025 (KR) 10-2025-0031891

(51) Int. Cl. H10K 59/80; H10K 59/12; H10K 59/122; H10K 59/124

(52) U.S. Cl. CPC H10K 59/873; H10K 59/1201; H10K 59/122; H10K 59/124

(57) ABSTRACT

Provided are a display device, an electronic device, and a method for manufacturing display device. A display device may include a substrate including a through hole and a display area surrounding the through hole; a display layer including a thin film transistor layer on the substrate, a light emitting element layer on the thin film transistor layer, an encapsulation layer on the light emitting element layer, and a sensor electrode layer on the encapsulation layer; a planarization film on the display layer; and a barrier dam between the display layer and the through hole. The planarization film may be on an upper portion of the display layer and inside a valley disposed between a side portion of the display layer and the barrier dam.

### CROSS-REFERENCE TO RELATED APPLICATION

This application claims priority from Korean Patent Application No. 10-2025-0031891 filed on Mar. 12, 2025 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device, an electronic device, and/or a method for manufacturing a display device.

### 2. Description of the Related Art

As the information society develops, the demand for display devices for displaying images has increased and diversified. The display devices may be display devices such as liquid crystal displays (LCDs), field emission displays (FEDs), or light emitting displays (LEDs). The light emitting display may include an organic light emitting display including organic light emitting diode elements as light emitting elements, an inorganic light emitting display including inorganic light emitting diode elements as light emitting elements, or the like.

As a display field that visually expresses electrical signal information rapidly develops, various display devices having excellent characteristics such as thinness, weight reduction, and low power consumption have been developed, and a display device in which a physical button or the like is removed on a front surface of the display device in order to expand a display area where an image is displayed and electronic elements such as a camera and a sensor are disposed in the display area has been introduced.

In order for the electronic elements such as the camera to be disposed in the display area, a light transmitting area through which light may be transmitted should exist in the display area, and the camera and the like may be located in such a light transmitting area.

### SUMMARY

Aspects of the present disclosure provide a display device, an electronic device, and a method for manufacturing a display device capable of limiting and/or preventing permeation of an etchant.

Aspects of the present disclosure also provide a display device, an electronic device, and a method for manufacturing a display device capable of limiting and/or minimizing a film lifting phenomenon during a detachment process.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a display device may include a substrate including a through hole and a display area surrounding the through hole; a display layer including a thin film transistor layer on the substrate, a light emitting element layer on the thin film transistor layer, an encapsulation layer on the light emitting element layer, and a sensor electrode layer on the encapsulation layer; a planarization film on the display layer; and a barrier dam between the display layer and the through hole. The planarization film may be on an upper portion of the display layer and inside a valley between a side portion of the display layer and the barrier dam.

In some embodiments, the planarization film may completely cover the upper portion of the display layer and the side portion of the display layer.

In some embodiments, the substrate further may further include a first removal area between the through hole and the barrier dam, and the display layer may not be disposed on the first removal area.

In some embodiments, the substrate may further include a cutting area between the first removal area and the through hole, and an edge of the through hole may be in the cutting area. An edge of the through hole may be defined by the substrate and may have a convex shape toward the through hole.

In some embodiments, the substrate may further include a second removal area between the barrier dam and the display layer, and the display layer may not be on the second removal area.

In some embodiments, the valley is may be in the second removal area.

In some embodiments, the thin film transistor layer may further include at least one transistor and at least one organic insulating film on the at least one transistor. The barrier dam may include a first sub-barrier dam on the substrate, and the first sub-barrier dam may include a same material as a material in the at least one organic insulating film.

In some embodiments, the light emitting element layer may include a plurality of light emitting elements and a pixel defining film. The plurality of light emitting elements may be configured to be driven by the at least one transistor. The pixel defining film may partition the plurality of light emitting elements. The barrier dam may further include a second sub-barrier dam on the first sub-barrier dam. A material of the second sub-barrier dam may be same as a material of the pixel defining film.

In some embodiments, the plurality of light emitting elements may be connected to each other by a common electrode. The plurality of light emitting elements may each include a pixel electrode, a light emitting layer, and a portion of the common electrode. The encapsulation layer may include at least one inorganic encapsulation film. The sensor electrode layer may include at least one sensor electrode and an inorganic film covering the at least one sensor electrode. The barrier dam may further include a third sub-barrier dam on the second sub-barrier dam. The third sub-barrier dam may include at least one of the light emitting layer, the common electrode, the at least one inorganic encapsulation film, and the inorganic film.

In some embodiments, the planarization film includes an acrylic organic material.

According to an aspect of the present disclosure, a method for manufacturing a display device may include forming a display cell on a first surface of a substrate; forming a first removal area and a second removal area in the display cell by irradiating the display cell with a first laser to remove a portion of the display cell; forming a planarization film and a protective film on the display cell; forming a sketch line for forming a through hole penetrating through the substrate by irradiating the substrate with a second laser; attaching an acid-resistant film onto the planarization film; reducing a thickness of the substrate and cutting the substrate along the sketch line by jetting an etchant onto a second surface of the substrate, wherein the second surface of the substrate may be opposite the first surface of the substrate; and forming the through hole by removing the acid-resistant film and a dummy. The dummy may correspond to a region of the substrate and a region of the display cell that are removed during the forming the through hole. The first removal area may be closer to the through hole compared to a distance between the through hole and the second removal area. A portion of the planarization film may be on the second removal area.

In some embodiments, the portion of the display cell removed during the forming the first removal area and the second removal area may include a first portion of the display cell to define the first removal area and a second portion of the display cell to define the second removal area. A third portion of the display cell may not be removed during the forming the first removal area and the second removal area. The third portion of the display cell may be between the first portion and the second portion. The third portion of the display cell may form a barrier dam such that when the portion of the display cell and the second portion of the display cell are removed by irradiating the display cell with the first laser, the third portion of display corresponding to the barrier dam remains between the first removal area and the second removal area.

In some embodiments, the barrier dam may be between the planarization film and the through hole.

In some embodiments, during the forming the sketch line, the sketch line may be formed in a location of the substrate overlapping the first removal area.

In some embodiments, during the forming the planarization film and the protective film on the display cell, the planarization film may be formed to completely cover an upper portion of a remaining portion of the display cell and a side portion of the remaining portion of the display cell, wherein the remaining portion of the display cell may not be enclosed by the second removal area.

In some embodiments, the method may include forming a filling member between the acid-resistant film and the planarization film.

In some embodiments, the filling member may be formed and when the filing member is formed, the planarization film may cover an upper surface of a remaining portion of the display cell and a side surface of the remaining portion of the display cell such that the filling member may not be in direct contact with the remaining portion of the display cell. The portion of the display cell removed during the forming the first removal area and the second removal area may include a first portion of the display cell to define the first removal area and a second portion of the display cell to define the second removal area. A third portion of the display cell may be between the first removal area and the second removal area and may define a barrier dam. The remaining portion of the display cell may be separate from the third portion of the display cell and the region of the display cell that is removed during the forming the through hole.

In some embodiments, after the forming the through hole, the through hole may be surrounded by the first removal area and the second removal area in plan view.

In some embodiments, each of the planarization film and the protective film each may include an acrylic organic material.

According to an aspect of the present disclosure, an electronic device may include a display device configured to display an image; a processor configured to provide an image driving signal to the display device; and a power module configured to supply power to the display device and the processor. The display device may include: a substrate including a through hole and a display area surrounding the through hole; a display layer including a thin film transistor layer on the substrate, a light emitting element layer on the thin film transistor layer, an encapsulation layer on the light emitting element layer, and a sensor electrode layer on the encapsulation layer; a planarization film on the display layer, and a barrier dam between the display layer and the through hole. The planarization film may be on an upper portion of the display layer and may be inside a valley between a side portion of the display layer and the barrier dam.

With a display device, an electronic device, and a method for manufacturing a display device according to an embodiment of the present disclosure, it is possible to limit and/or prevent permeation of an etchant.

With the display device, the electronic device, and the method for manufacturing a display device according to an embodiment of the present disclosure, it is possible to limit and/or minimize a film lifting phenomenon.

The effects of the present disclosure are not limited to the aforementioned effects, and various other effects are described in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a plan view illustrating a display panel and driving integrated chips (ICs) according to an embodiment;

FIG. 3 is a cross-sectional view taken along line X1-X1′ of FIG. 1;

FIG. 4 is a cross-sectional view illustrating a state in which the display device of FIG. 3 is bent;

FIG. 5 is a cross-sectional view illustrating an example of a cross section of a display area of the display device according to an embodiment;

FIG. 6 is an enlarged view of area A of FIG. 2;

FIG. 7 is a cross-sectional view taken along line X2-X2′ of FIG. 5;

FIG. 8 is an enlarged view of area B of FIG. 7;

FIG. 9 is a flowchart illustrating a method for manufacturing a display device according to an embodiment;

FIG. 10 is a perspective view illustrating S110 of FIG. 9;

FIG. 11 is a cross-sectional view illustrating S110 of FIG. 9;

FIG. 12 is a perspective view illustrating S120 of FIG. 9;

FIG. 13 is a cross-sectional view illustrating S120 of FIG. 9;

FIG. 14 is a cross-sectional view illustrating S130 of FIG. 9;

FIG. 15 is a perspective view illustrating S140 of FIG. 9;

FIG. 16 is a cross-sectional view illustrating S140 of FIG. 9;

FIG. 17 is a cross-sectional view illustrating an example of S150 of FIG. 9;

FIG. 18 is a cross-sectional view illustrating another example of S150 of FIG. 9;

FIG. 19 is a perspective view illustrating S160 of FIG. 9;

FIG. 20 is a cross-sectional view illustrating an example of S160 of FIG. 9;

FIG. 21 is a cross-sectional view illustrating another example of S160 of FIG. 9;

FIG. 22 is a perspective view illustrating S170 of FIG. 9;

FIG. 23 is a cross-sectional view illustrating S170 of FIG. 9;

FIG. 24 is a block diagram of an electronic device according to an embodiment; and

FIG. 25 is schematic views of electronic devices according to various embodiments.

### DETAILED DESCRIPTION OF THE EMBODIMENTS

Inventive concepts will now be described more fully hereinafter with reference to the accompanying drawings, in which example embodiments of inventive concepts are shown. Inventive concepts may, however, be embodied in different forms and should not be construed as limited to the embodiments set forth herein. Rather, these embodiments are provided so that this disclosure will be thorough and complete, and will filly convey the scope of inventive concepts to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, embodiments of the present disclosure will be described in detail with reference to the accompanying drawings.

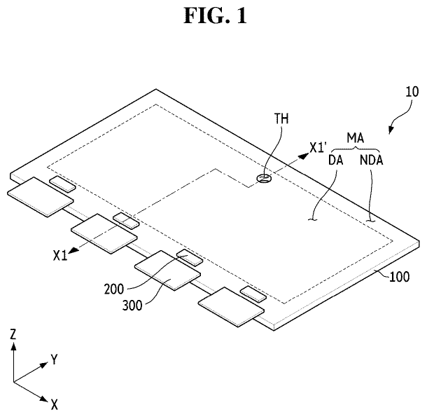

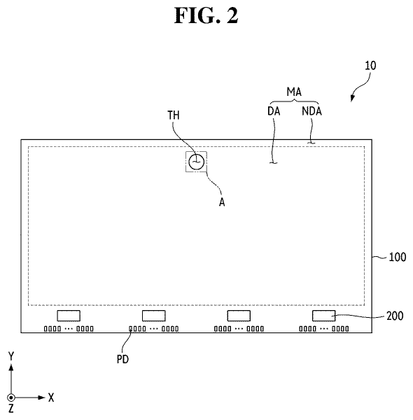

FIG. 1 is a perspective view illustrating a display device according to an embodiment. FIG. 2 is a plan view illustrating a display panel and driving integrated chips (ICs) according to an embodiment.

Referring to FIGS. 1 and 2, a display device 10 according to an embodiment may be a device that displays a moving image or a still image, and may be used as a display screen of various products such as televisions, laptop computers, monitors, billboards, and the Internet of Things (IOT) devices as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs).

The display device 10 according to an embodiment may be a light emitting display such as an organic light emitting display using organic light emitting diodes, a quantum dot light emitting display including quantum dot light emitting layers, an inorganic light emitting display including inorganic semiconductors, and a micro light emitting display using micro or nano light emitting diodes (micro LEDs or nano LEDs). Hereinafter, it will be mainly described that the display device 10 is the organic light emitting display, but the present disclosure is not limited thereto.

The display device 10 according to an embodiment may include a display panel 100, driving ICs 200, and circuit boards 300.

The display panel 100 may be formed in a rectangular shape, in plan view, having long sides in a first direction (X-axis direction) and short sides in a second direction (Y-axis direction) crossing the first direction (X-axis direction). A corner where the long side in the first direction (X-axis direction) and the short side in the second direction (Y-axis direction) meet may be right-angled or rounded with a curvature. A shape of the display panel 100 in plan view is not limited to the rectangular shape, and may be other polygonal shapes, a circular shape, or an elliptical shape.

In the drawings, the first direction (X-axis direction) and the second direction (Y-axis direction) are horizontal directions, respectively, and cross each other. For example, the first direction (X-axis direction) and the second direction (Y-axis direction) may be orthogonal to each other. In addition, a third direction (Z-axis direction) may be a perpendicular direction crossing, for example, orthogonal to, the first direction (X-axis direction) and the second direction (Y-axis direction). In the present disclosure, directions indicated by arrows of the first to third directions (X-axis direction, Y-axis direction, and Z-axis direction) may be referred to as one side, and directions opposite to the one side may be referred to as the other side.

The display panel 100 may be formed to be flat, but is not limited thereto. For example, the display panel 100 may include curved surface portions formed at left and right ends thereof and having a constant curvature or a variable curvature. In addition, the display panel 100 may be flexibly formed to be curved, bent, folded, or rolled.

The display panel 100 may include a display area DA displaying an image and a non-display area NDA disposed around the display area DA. The display area DA and the non-display area NDA may constitute a main area MA.

The display area DA may occupy most of the area of the display panel 100. The display area DA may be disposed at the center of the display panel 100. Pixels respectively including a plurality of emission areas in order to display an image may be disposed in the display area DA.

The non-display area NDA may neighbor the display area DA. The non-display area NDA may be an area outside the display area DA. The non-display area NDA may surround the display area DA. The non-display area NDA may be an edge area of the display panel 100.

Display pads PD may be disposed in the non-display area NDA in order to be connected to the circuit boards 300. The display pads PD may be disposed on an edge of one side of the display panel 100. For example, the display pads PD may be disposed on an edge of a lower side of the display panel 100.

The driving ICs 200 may generate data voltages, source voltages, scan timing signals, and the like. The driving ICs 200 may output the data voltages, the source voltages, the scan timing signals, and the like.

The driving ICs 200 may be disposed between the display pads PD and the display area DA in the non-display area NDA. Each of the driving ICs 200 may be attached to the non-display area NDA of the display panel 100 in a chip on glass (COG) manner. Alternatively, each of the driving ICs 200 may be attached to the circuit board 300 in a chip on plastic (COP) manner.

The circuit boards 300 may be disposed on the display pads PD disposed on the edge of one side of the display panel 100. The circuit boards 300 may be attached to the display pads PD using a conductive adhesive member such as an anisotropic conductive film and an anisotropic conductive adhesive. For this reason, the circuit boards 300 may be electrically connected to signal lines of the display panel 100. Each of the circuit boards 300 may be a flexible printed circuit board or a flexible film such as a chip on film.

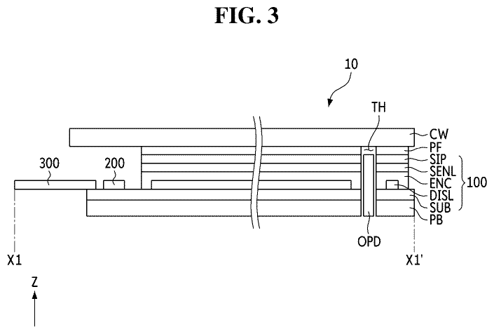

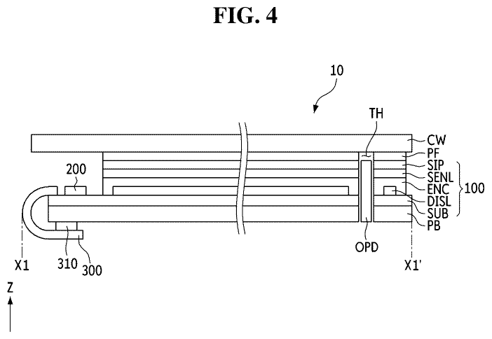

FIG. 3 is a cross-sectional view taken along line X1-X1′ of FIG. 1. FIG. 4 is a cross-sectional view illustrating a state in which the display device of FIG. 3 is bent.

Referring to FIGS. 3 and 4 in addition to FIGS. 1 and 2, the display device 10 according to an embodiment may include the display panel 100, a polarizing film PF, a cover window CW, a panel lower cover PB, the driving IC 200, and the circuit board 300. The display panel 100 may include a substrate SUB, a display layer DISL, an encapsulation layer ENC, a sensor electrode layer SENL, and a planarization film SIP.

The substrate SUB may have a rigid material. For example, the substrate SUB may be made of glass. The substrate SUB may be made of ultra-thin glass (UTG) having a thickness of approximately 500 μm or less. In some embodiments, a thickness of the substrate SUB may be approximately 200 μm. In another embodiment, the substrate SUB may include a first substrate having a rigid material and a second substrate made of a polymer resin having a flexible material.

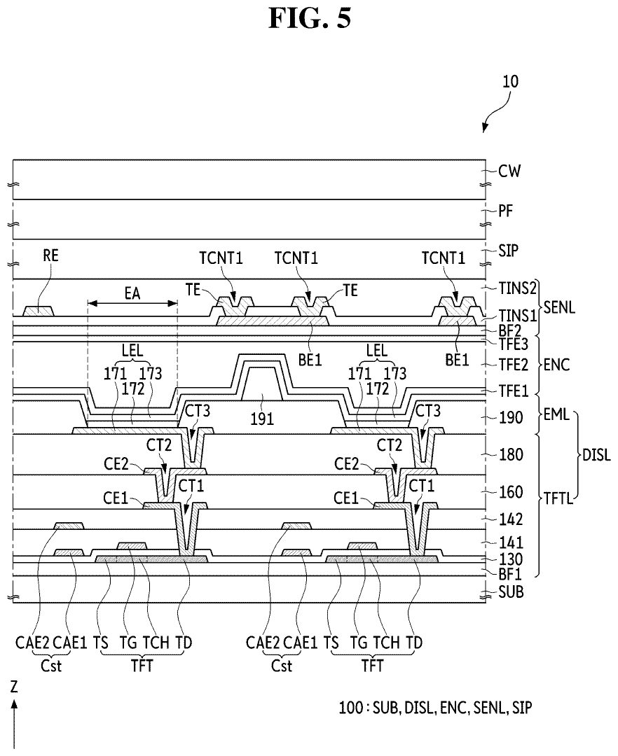

The display layer DISL may be disposed on a first surface of the substrate SUB. The display layer DISL may be a layer displaying an image. The display layer DISL may include a thin film transistor layer TFTL (see FIG. 5) in which thin film transistors are formed and a light emitting element layer EML (see FIG. 5) in which light emitting elements emitting light are disposed in emission areas.

Scan lines, data lines, power lines, and the like, for the emission areas to emit light may be disposed in the display area DA of the display layer DISL. A scan driving circuit unit outputting scan signals to the scan lines, fan-out lines connecting the data lines and the driving IC 200 to each other, and the like, may be disposed in the non-display area NDA of the display layer DISL.

The encapsulation layer ENC may be a layer for encapsulating the light emitting element layer of the display layer DISL in order to limit and/or prevent oxygen or moisture from permeating into the light emitting element layer of the display layer DISL. The encapsulation layer ENC may be disposed on the display layer DISL. The encapsulation layer ENC may be disposed on an upper surface and side surfaces of the display layer DISL. The encapsulation layer ENC may cover the display layer DISL.

The sensor electrode layer SENL may be disposed on the encapsulation layer ENC. The sensor electrode layer SENL may include sensor electrodes. The sensor electrode layer SENL may sense a user's touch using the sensor electrodes.

The planarization film SIP may be disposed on the sensor electrode layer SENL. The planarization film SIP may planarize a flexure formed by patterns disposed below the planarization film SIP. The planarization film SIP may be a single film or multiple films made of an organic material. For example, the planarization film SIP may be formed as an organic film made of an acrylic resin, an epoxy resin, a phenolic resin, a polyamide resin, a polyimide resin, or the like.

The polarizing film PF may be disposed on the planarization film SIP. The polarizing film PF may be disposed on the display panel 100 in order to reduce external light reflection. The polarizing film PF may include a first base member, a linear polarizer, a phase retardation film such as a λ/4 plate (quarter-wave plate), and a second base member. The first base member, the phase retardation film, the linear polarizer, and the second base member of the polarizing film PF may be sequentially stacked on the display panel 100.

The cover window CW may be disposed on the polarizing film PF. The cover window CW may be attached onto the polarizing film PF by a transparent adhesive member such as an optically clear adhesive (OCA) film.

The panel lower cover PB may be disposed on a second surface of the substrate SUB of the display panel 100. The second surface of the substrate SUB may be a surface opposite to the first surface of the substrate SUB. The panel lower cover PB may be attached to the second surface of the substrate SUB of the display panel 100 by an adhesive member. The adhesive member may be a pressure sensitive adhesive (PSA).

The panel lower cover PB may include at least one of a light blocking member for absorbing light incident from the outside, a buffer member for absorbing impact from the outside, and a heat dissipation member for efficiently dissipating heat of the display panel 100.

The driving IC 200 and the circuit board 300 may be bent toward a lower portion of the display panel 100 as illustrated in FIG. 4. The circuit board 300 may be attached to a lower surface of the panel lower cover PB using an adhesive member 310. The adhesive member 310 may be a pressure sensitive adhesive.

The display device 10 may further include a through hole TH and an optical device OPD disposed in the through hole TH.

The through hole TH is a hole capable of transmitting light, and may be a physical hole penetrating through the panel lower cover PB and the polarizing film PF as well as the display panel 100. For example, the through hole TH may penetrate through the substrate SUB, the display layer DISL, the encapsulation layer ENC, and the sensor electrode layer SENL of the display panel 100. However, the present disclosure is not limited thereto, and the through hole TH may penetrate through the panel lower cover PB, but may not penetrate through the display panel 100 and the polarizing film PF. The cover window CW may cover the through hole TH.

The optical device OPD may be spaced apart from the display panel 100, the panel lower cover PB, and the polarizing film PF. The optical device OPD may be an optical sensor sensing light incident through the through hole TH, such as a proximity sensor, an illuminance sensor, and a camera sensor.

FIG. 5 is a cross-sectional view illustrating an example of a cross section of a display area of the display device according to an embodiment.

Referring to FIG. 5, the display device 10 according to an embodiment may include a display panel 100, a polarizing film PF, and a cover window CW.

In an embodiment, the display panel 100 may be an organic light emitting display panel including light emitting elements LEL each including an organic light emitting layer 172. The display panel 100 may include a substrate SUB, a display layer DISL, an encapsulation layer ENC, a sensor electrode layer SENL, and a planarization film SIP. The display layer DISL may include a thin film transistor layer TFTL including a plurality of thin film transistors and a light emitting element layer EML including a plurality of light emitting elements.

The substrate SUB may have a rigid material. For example, the substrate SUB may be made of glass. The substrate SUB may be made of ultra-thin glass (UTG) having a thickness of approximately 500 μm or less. In some embodiments, a thickness of the substrate SUB may be approximately 200 μm. In another embodiment, the substrate SUB may include a first substrate having a rigid material and a second substrate made of a polymer resin having a flexible material.

The thin film transistor layer TFTL may include a first buffer film BF1, thin film transistors TFT, a gate insulating film 130, a first interlayer insulating film 141, capacitors Cst, a second interlayer insulating film 142, a first data metal layer, a first organic film 160, a second data metal layer, and a second organic film 180.

The first buffer film BF1 may be disposed on the substrate SUB. The first buffer film BF1 may be a film made of an inorganic material, such as a silicon nitride layer, a silicon oxynitride layer, a silicon oxide layer, a titanium oxide layer, and an aluminum oxide layer. Alternatively, the first buffer film BF1 may be formed as multiple films in which a plurality of layers of a silicon nitride layer, a silicon oxynitride layer, a silicon oxide layer, a titanium oxide layer, and an aluminum oxide layer are alternately stacked.

An active layer including a channel region TCH, a source region TS, and a drain region TD of the thin film transistor TFT may be disposed on the first buffer film BF1. The active layer may be made of polycrystalline silicon, single crystal silicon, low-temperature polycrystalline silicon, amorphous silicon, or an oxide semiconductor material. When the active layer includes the polycrystalline silicon or the oxide semiconductor material, the source region TS and drain region TD in the active layer may be conductive regions doped with ions or impurities to have conductivity.

The gate insulating film 130 may be disposed on the active layers of the thin film transistors TFT. The gate insulating film 130 may be formed as an inorganic film such as a silicon nitride layer, a silicon oxynitride layer, a silicon oxide layer, a titanium oxide layer, or an aluminum oxide layer.

A first gate metal layer including gate electrodes TG of the thin film transistors TFT, first capacitor electrodes CAE1 of the capacitors Cst, and scan lines may be disposed on the gate insulating film 130. The gate electrode TG of the thin film transistor TFT may overlap the channel region TCH in the third direction (Z-axis direction). The first gate metal layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first interlayer insulating film 141 may be disposed on the first gate metal layer. The first interlayer insulating film 141 may be formed as an inorganic film such as a silicon nitride layer, a silicon oxynitride layer, a silicon oxide layer, a titanium oxide layer, or an aluminum oxide layer. The first interlayer insulating film 141 may include a plurality of inorganic films.

A second gate metal layer including second capacitor electrodes CAE2 of the capacitors Cst may be disposed on the first interlayer insulating film 141. The second capacitor electrode CAE2 may overlap the first capacitor electrode CAE1 in the third direction (Z-axis direction). Therefore, the capacitor Cst may be formed by the first capacitor electrode CAE1, the second capacitor electrode CAE2, and an inorganic insulating dielectric film disposed between the first capacitor electrode CAE1 and the second capacitor electrode CAE2 and serving as a dielectric film. The second gate metal layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second interlayer insulating film 142 may be disposed on the second gate metal layer. The second interlayer insulating film 142 may be formed as an inorganic film such as a silicon nitride layer, a silicon oxynitride layer, a silicon oxide layer, a titanium oxide layer, or an aluminum oxide layer. The second interlayer insulating film 142 may include a plurality of inorganic films.

The first data metal layer including first connection electrodes CE1 and data lines may be disposed on the second interlayer insulating film 142. The first connection electrode CE1 may be connected to the drain region TD through a first connection contact hole CT1 penetrating through the gate insulating film 130, the first interlayer insulating film 141, and the second interlayer insulating film 142. The first data metal layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The first organic film 160 for planarizing a step due to the thin film transistors TFT may be disposed on the first connection electrodes CE1. The first organic film 160 may be formed as an organic film made of an acrylic resin, an epoxy resin, a phenolic resin, a polyamide resin, a polyimide resin, or the like.

The second data metal layer including second connection electrodes CE2 may be disposed on the first organic film 160. The second data metal layer may be connected to the first connection electrode CE1 through a second contact hole CT2 penetrating through the first organic film 160. The second data metal layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second organic film 180 may be disposed on the second connection electrodes CE2. The second organic film 180 may be formed as an organic film made of an acrylic resin, an epoxy resin, a phenolic resin, a polyamide resin, a polyimide resin, or the like.

The second data metal layer including the second connection electrodes CE2 and the second organic film 180 may be omitted.

The light emitting element layer EML is disposed on the thin film transistor layer TFTL. The light emitting element layer EML may include light emitting elements LEL and a pixel defining film 190.

Each of the light emitting elements LEL may include a pixel electrode 171, a light emitting layer 172, and a common electrode 173. Each of emission areas EA refers to an area where the pixel electrode 171, the light emitting layer 172, and the common electrode 173 are sequentially stacked and holes from the pixel electrode 171 and electrons from the common electrode 173 combine with each other in the light emitting layer 172 to emit light. In this case, the pixel electrode 171 may be an anode electrode, and the common electrode 173 may be a cathode electrode.

A pixel electrode layer including the pixel electrodes 171 may be formed on the second organic film 180. The pixel electrode 171 may be connected to the second connection electrode CE2 through a third connection hole CT3 penetrating through the second organic film 180. The pixel electrode layer may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

In a top emission structure in which light is emitted toward the common electrode 173 based on the light emitting layer 172, the pixel electrode 171 may be formed as a single layer made of molybdenum (Mo), titanium (Ti), copper (Cu), or aluminum (Al) or be formed as a stacked structure (Ti/Al/Ti) of aluminum and titanium, a stacked structure (ITO/Al/ITO) of aluminum and indium tin oxide (ITO), an APC alloy, and a stacked structure (ITO/APC/ITO) of an APC alloy and ITO in order to increase reflectivity. The APC alloy is an alloy of silver (Ag), palladium (Pd), and copper (Cu).

The pixel defining film 190 serves to define the emission areas EA of the pixels. To this end, the pixel defining film 190 may expose partial areas of the pixel electrodes 171 on the second organic film 180. The pixel defining film 190 may cover edges of the pixel electrodes 171. The pixel defining film 190 may be disposed in the third contact holes CT3. That is, the third contact holes CT3 may be filled with the pixel defining film 190. The pixel defining film 190 may be formed as an organic film made of an acrylic resin, an epoxy resin, a phenolic resin, a polyamide resin, a polyimide resin, or the like.

A spacer 191 may be disposed on the pixel defining film 190. The spacer 191 may serve to support a mask during a process of manufacturing the light emitting layer 172. The spacer 191 may be formed as an organic film made of an acrylic resin, an epoxy resin, a phenolic resin, a polyamide resin, a polyimide resin, or the like.

The light emitting layer 172 is formed on the pixel electrode 171. The light emitting layer 172 may include an organic material to emit light of a selected color. For example, the light emitting layer 172 may include a hole transporting layer, an organic material layer, and an electron transporting layer. The organic material layer may include a host and a dopant. The organic material layer may include a material emitting selected light, and may be formed using a phosphorescent material or a fluorescent material.

The common electrode 173 is formed on the light emitting layer 172. The common electrode 173 may cover the light emitting layer 172. The common electrode 173 may be a common layer formed in common in the emission areas EA. A capping layer may be formed on the common electrode 173.

In the top emission structure, the common electrode 173 may be made of a transparent conductive material (TCO) such as ITO or indium zinc oxide (IZO) capable of transmitting light or a semi-transmissive conductive material such as magnesium (Mg), silver (Ag), or an alloy of magnesium (Mg) and silver (Ag). When the common electrode 173 is made of the semi-transmissive conductive material, light emission efficiency may be increased by a micro cavity.

The encapsulation layer ENC may be disposed on the light emitting element layer EML. The encapsulation layer ENC may include at least one inorganic film TFE1 or TFE3 in order to limit and/or prevent oxygen or moisture from permeating into the light emitting element layer EML. In addition, the encapsulation layer ENC may include at least one organic film TFE2 in order to protect the light emitting element layer EML from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be disposed on the common electrode 173, the encapsulation organic film TFE2 may be disposed on the first encapsulation inorganic film TFE1, and the second encapsulation inorganic film TFE3 may be disposed on the encapsulation organic film TFE2. Each of the first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of an acrylic resin, an epoxy resin, a phenolic resin, a polyamide resin, a polyimide resin, or the like.

The sensor electrode layer SENL may be disposed on the encapsulation layer ENC. The sensor electrode layer SENL may include a second buffer film BF2, first connection portions BE1, a first sensor insulating film TINS1, sensor electrodes TE and RE, and a second sensor insulating film TINS2.

The second buffer film BF2 may be disposed on the encapsulation layer ENC. The second buffer film BF2 may include at least one inorganic film. For example, the second buffer film BF2 may be formed as multiple films in which one or more inorganic films of a silicon nitride layer, a silicon oxynitride layer, a silicon oxide layer, a titanium oxide layer, and an aluminum oxide layer are alternately stacked. The second buffer film BF2 may be omitted.

The first connection portions BE1 may be disposed on the second buffer film BF2. The first connection portions BE1 may be formed as a single layer made of molybdenum (Mo), titanium (Ti), copper (Cu), or aluminum (Al) or formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The first sensor insulating film TINS1 may be disposed on the first connection portions BE1. The first sensor insulating film TINS1 may be formed as an inorganic film such as a silicon nitride layer, a silicon oxynitride layer, a silicon oxide layer, a titanium oxide layer, or an aluminum oxide layer.

The sensor electrodes, that is, driving electrodes TE and sensing electrodes RE, may be disposed on the first sensor insulating film TINS1. In addition, dummy patterns may be disposed on the first sensor insulating film TINS1. The driving electrodes TE, the sensing electrodes RE, and the dummy patterns do not overlap the emission areas EA. Each of the driving electrodes TE, the sensing electrodes RE, and the dummy patterns may be formed as a single layer made of molybdenum (Mo), titanium (Ti), copper (Cu), or aluminum (Al) or formed as a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO.

The second sensor insulating film TINS2 may be disposed on the driving electrodes TE, the sensing electrodes RE, and the dummy patterns. The second sensor insulating film TINS2 may include at least one of an inorganic film and an organic film. The inorganic film may be a silicon nitride layer, a silicon oxynitride layer, a silicon oxide layer, a titanium oxide layer, or an aluminum oxide layer. The organic film may be made of an acrylic resin, an epoxy resin, a phenolic resin, a polyamide resin, or a polyimide resin.

The planarization film SIP may be disposed on the second sensor insulating film TINS2 of the sensor electrode layer SENL. The planarization film SIP may planarize a flexure formed by patterns disposed below the planarization film SIP. For example, the flexure formed by the first connection portions BE1, the driving electrodes TE, and the sensing electrodes RE may be planarized to some extent by the second sensor insulating film TINS2, but when a thickness of the second sensor insulating film TINS2 is not sufficiently great, the flexure formed by the first connection portions BE1, the driving electrodes TE, and the sensing electrodes RE may still be exposed on an upper surface of the second sensor insulating film TINS2. The planarization film SIP may planarize even the flexure that is not completely planarized by the second sensor insulating film TINS2 as described above.

The planarization film SIP may be a single film or multiple films made of an organic material. For example, the planarization film SIP may be formed as an organic film made of an acrylic resin, an epoxy resin, a phenolic resin, a polyamide resin, a polyimide resin, or the like.

The polarizing film PF may be disposed on the sensor electrode layer SENL. The polarizing film PF may be disposed on the display panel 100 in order to reduce external light reflection. The polarizing film PF may include a first base member, a linear polarizer, a phase retardation film such as a λ/4 plate (quarter-wave plate), and a second base member. The first base member, the phase retardation film, the linear polarizer, and the second base member of the polarizing film PF may be sequentially stacked on the display panel 100.

The cover window CW may be disposed on the polarizing film PF. The cover window CW may be attached onto the polarizing film PF by a transparent adhesive member such as an optically clear adhesive (OCA) film.

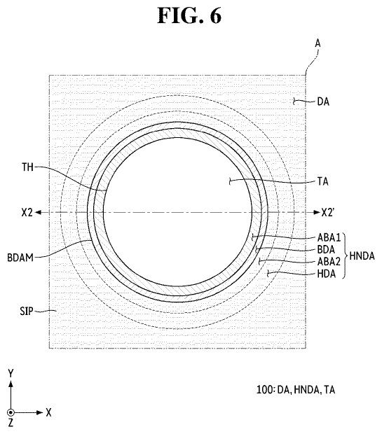

FIG. 6 is an enlarged view of area A of FIG. 2.

Referring to FIG. 6 in addition to FIG. 5, the display panel 100 according to an embodiment may include a display area DA, a hole non-display area HNDA, and a transmissive area TA.

The display area DA is an area where light may be emitted because the light emitting elements LEL are disposed. The transmissive area TA is an area where the through hole TH is disposed. The transmissive area TA may be surrounded by the display area DA in plan view.

The hole non-display area HNDA is an area where light is not emitted because the light emitting elements LEL are not disposed. The hole non-display area HNDA may be surrounded by the display area DA in plan view. The hole non-display area HNDA may be disposed between the transmissive area TA and the display area DA.

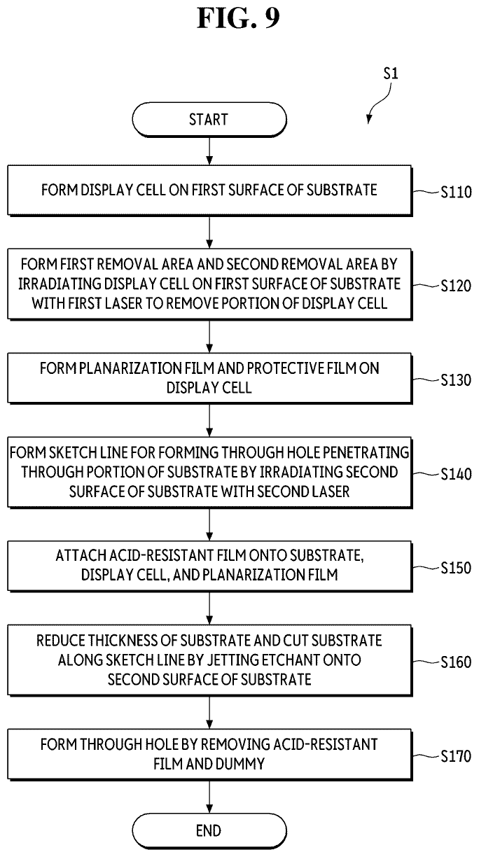

The hole non-display area HNDA may be an area for inorganic encapsulation, line bypass, and etchant permeation prevention. For example, the hole non-display area HNDA may include a structure for limiting and/or preventing oxygen or moisture from permeating into the light emitting element layer EML of the display layer DISL due to the through hole TH by causing the first encapsulation inorganic film TFE1 and the second encapsulation inorganic film TFE3 of the encapsulation layer ENC to be in contact with each other. In addition, the hole non-display area HNDA may include a structure for various types of lines, embedded circuits, and the like, to bypass the through hole TH. In addition, the hole non-display area HNDA may include a structure for limiting and/or preventing an etchant from permeating into the light emitting element layer EML in an etching process of a method S1 (see FIG. 9) for manufacturing a display device to be described later.

The hole non-display area HNDA may include a hole dam area HDA, a first removal area ABA1, a barrier dam area BDA, and a second removal area ABA2.

The first removal area ABA1 may surround the through hole TH (or the transmissive area TA) in plan view. The first removal area ABA1 may be an area where the display layer DISL, the light emitting element layer EML, the encapsulation layer ENC, and the sensor electrode layer SENL disposed on the substrate SUB are removed. In the first removal area ABA1, the display layer DISL, the light emitting element layer EML, the encapsulation layer ENC, and the sensor electrode layer SENL may be removed to expose an upper surface of the substrate SUB.

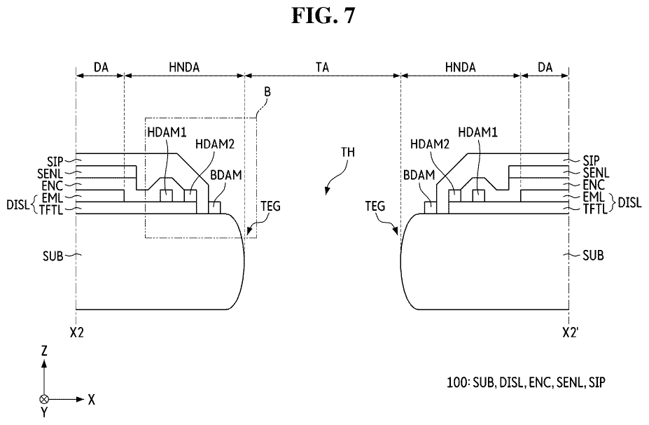

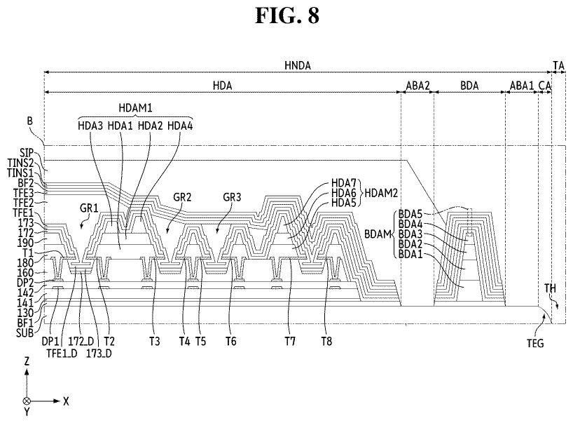

The barrier dam area BDA may surround the first removal area ABA1 in plan view. The barrier dam area BDA may be located between the first removal area ABA1 and the second removal area ABA2. The barrier dam area BDA may be an area where the display layer DISL, the light emitting element layer EML, the encapsulation layer ENC, and the sensor electrode layer SENL disposed on the substrate SUB remain without being removed, unlike the first removal area ABA1 and the second removal area ABA2. A barrier dam BDAM may be disposed in the barrier dam area BDA. The barrier dam BDAM will be described later with reference to FIGS. 7 and 8.

The second removal area ABA2 may surround the barrier dam BDAM in plan view. The second removal area ABA2 may be an area where the display layer DISL, the light emitting element layer EML, the encapsulation layer ENC, and the sensor electrode layer SENL disposed on the substrate SUB are removed. In the second removal area ABA2, the display layer DISL, the light emitting element layer EML, the encapsulation layer ENC, and the sensor electrode layer SENL may be removed to expose the upper surface of the substrate SUB.

The hole dam area HDA may surround the second removal area ABA2 in plan view. The hole dam area HDA may include a structure for limiting and/or preventing oxygen or moisture from permeating into the light emitting element layer EML of the display layer DISL due to the through hole TH. In addition, the hole dam area HDA may include a structure for various types of lines, embedded circuits, and the like, to bypass the through hole TH. The hole dam area HDA may include at least one dam, at least one tip, and at least one groove. For example, the hole dam area HDA may include a first hole dam HDAM1 (see FIG. 8), a second hole dam HDAM2 (see FIG. 8), first to eighth tips T1 to T8 (see FIG. 8), and first to third grooves GR1 to GR3 (see FIG. 8), as illustrated in FIG. 8 to be described later.

The display device 10 according to the present embodiment may have improved durability by including the planarization film SIP disposed across the display area DA and the hole non-display area HNDA and the barrier dam BDAM disposed in the hole non-display area HNDA. For example, the planarization film SIP and the barrier dam BDAM may limit and/or prevent an etchant from permeating into the light emitting element layer EML in an etching process of a method S1 (see FIG. 9) for manufacturing a display device to be described later, and may limit and/or prevent film lifting in an acid-resistant film detachment process of a method S1 (see FIG. 9) for manufacturing a display device to be described later. This will be described later with reference to FIG. 9 or the like.

FIG. 7 is a cross-sectional view taken along line X2-X2′ of FIG. 5. FIG. 8 is an enlarged view of area B of FIG. 7.

Referring to FIGS. 7 and 8 in addition to FIG. 6, the display panel 100 may include the display area DA, the hole non-display area HNDA, and the transmissive area TA. The hole non-display area HNDA may include the hole dam area HDA, the first removal area ABA1, the barrier dam area BDA, and the second removal area ABA2. In some embodiments, the hole non-display area HNDA may further include a cutting area CA.

The hole dam area HDA may include a structure for limiting and/or preventing oxygen or moisture from permeating into the light emitting element layer EML of the display layer DISL due to the through hole TH. In addition, the hole dam area HDA may include a structure for various types of lines, embedded circuits, and the like, to bypass the through hole TH. In an embodiment, a width of the hole dam area HAD in the first direction (X-axis direction) may be approximately 100 μm to 300 μm.

The hole dam area HDA may include at least one dam, at least one tip, and at least one groove. For example, the hole dam area HDA may include a first hole dam HDAM1, a second hole dam HDAM2, first to eighth tips T1 to T8, and first to third grooves GR1 to GR3.

The first tip T1 and the second tip T2 may be more adjacent to the display area DA than the first hole dam HDAM1 is. In other words, a distance from the first tip T1 and the second tip T2 to the display area DA may be less than a distance from the first hole dam HDAM1 to the display area DA. The first tip T1 may be more adjacent to the display area DA than the second tip T2 is. In other words, a distance from the first tip T1 and to the display area DA may be less than a distance from the second tip T2 to the display area DA. The second tip T2 may be disposed between the first tip T1 and the first hole dam HDAM1.

The third tip T3, the fourth tip T4, the fifth tip T5, and the sixth tip T6 may be disposed between the first hole dam HDAM1 and the second hole dam HDAM2. At least a portion of the third tip T3 may overlap the first hole dam HDAM1 in the third direction (Z-axis direction).

The seventh tip T7 and the eighth tip T8 may be more adjacent to the through hole TH than the second hole dam HDAM2 is. At least a portion of the seventh tip T7 may overlap the second hole dam HDAM2 in the third direction (Z-axis direction). The eighth tip T8 may be disposed between the second hole dam HDAM2 and the through hole TH.

The first groove GR1 may be disposed between the first tip T1 and the second tip T2. The second groove GR2 may be disposed between the third tip T3 and the fourth tip T4. The third groove GR3 may be disposed between the fifth tip T5 and the sixth tip T6.

A first dummy pattern DP1 may include the same material as the second gate metal layer including the second capacitor electrode CAE2 (see FIG. 5) of the capacitor Cst (see FIG. 5), and may be disposed at a same layer as the second gate metal layer. For example, the first dummy pattern DP1 may be disposed on the first interlayer insulating film 141. The first dummy pattern DP1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

A second dummy pattern DP2 may include the same material as the first data metal layer including the first connection electrode CE1 (see FIG. 5) and the data lines, and may be disposed at a same layer as the first data metal layer. For example, the second dummy pattern DP2 may be disposed on the second interlayer insulating film 142. The second dummy pattern DP2 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second dummy pattern DP2 may overlap the first dummy pattern DP1 in the third direction (Z-axis direction).

The first to eighth tips T1 to T8 may include the same material as the second data metal layer including the second connection electrode CE2 (see FIG. 5), and may be disposed at a same layer as the second data metal. For example, the first to eighth tips T1 to T8 may be disposed on the first organic film 160. Each of the first to eighth tips T1 to T8 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

Each of the first to eighth tips T1 to T8 may be connected to the second dummy pattern DP2 through a contact hole penetrating through the first organic film 160. Each of the first to eighth tips T1 to T8 may include an eaves structure in which upper and lower surfaces of each of the first to eighth tips T1 to T8 are exposed without being covered by the first organic film 160, the second organic film 180, the first hole dam HDAM1, and the second hole dam HDAM2. The fourth tip T4 and the fifth tip T5 may be formed integrally with each other. Each of the first to eighth tips T1 to T8 may be a protrusion pattern or a trench pattern for forming a groove (or a trench).

The first groove GR1 may be disposed between the first tip T1 and the second tip T2, the second groove GR2 may be disposed between the third tip T3 and the fourth tip T4, and the third groove GR3 may be disposed between the fifth tip T5 and the sixth tip T6. The first groove GR1 may have eaves structures formed by the first tip T1 and the second tip T2, the second groove GR2 may have eaves structures formed by the third tip T3 and the fourth tip T4, and the third groove GR3 may have eaves structures formed by the fifth tip T5 and the sixth tip T6.

Since the light emitting layer 172 is deposited by evaporation and the common electrode 173 is deposited by sputtering, the light emitting layer 172 and the common electrode 173 may have low step coverage, and may thus be disconnected in each of the first to third grooves GR1, GR2, and GR3. In contrast, since the first encapsulation inorganic film TFE1 and the second encapsulation inorganic film TFE3 are deposited by chemical vapor deposition, atomic layer deposition, and the like, the first encapsulation inorganic film TFE1 and the second encapsulation inorganic film TFE3 may have high step coverage, and may thus be connected without being disconnected in each of the first to third grooves GR1, GR2, and GR3. For example, a disconnected light emitting layer residue 172_D and a disconnected common electrode residue 173_D may be disposed in each of the first to third grooves GR1, GR2, and GR3. The step coverage refers to a ratio of a degree at which a thin film is coated on an inclined portion to a degree at which a thin film is coated on a flat portion.

The first hole dam HDAM1 may include first to fourth hole sub-dams HDA1, HDA2, HDA3, and HDA4. The first hole sub-dam HDA1 may be disposed on the first organic film 160 and may include the same material as the second organic film 180. The first hole sub-dam HDA1 may be disposed on the second tip T2 and the third tip T3. The second hole sub-dam HDA2 may be disposed on the first hole sub-dam HDA1 and may include the same material as the pixel defining film 190. The third hole sub-dam HDA3 and the fourth hole sub-dam HDA4 may be disposed on the second hole sub-dam HDA2 and may include the same material as the spacer 191, but are not limited thereto. The fourth hole sub-dam HDA4 may be more adjacent to the through hole TH than the third hole sub-dam HDA3 is. A thickness of the fourth hole sub-dam HDA4 may be greater than a thickness of the third hole sub-dam HDA3.

The second hole dam HDAM2 may include lude fifth to seventh hole sub-dams HDA5, HDA6, and HDA7. The fifth hole sub-dam HDA5 may be disposed on the first organic film 160 and may include the same material as the second organic film 180. The fifth hole sub-dam HDA5 may be disposed on the seventh tip T7. The sixth hole sub-dam HDA6 may be disposed on the fifth hole sub-dam HDA5 and may include the same material as the pixel defining film 190. The seventh hole sub-dam HDA7 may be disposed on the sixth hole sub-dam HDA6 and may include the same material as the spacer 191, but is not limited thereto.

It is possible to limit and/or prevent the encapsulation organic film TFE2 from overflowing into the through hole TH by the first hole dam HDAM1 and the second hole dam HDAM2.

The light emitting layer 172, the common electrode 173, the first encapsulation inorganic film TFE1, the second encapsulation inorganic film TFE3, the second buffer film BF2, the first sensor insulating film TINS1, and the second sensor insulating film TINS2 may extend to the barrier dam area BDA except for portions removed in the second removal area ABA2. An end of the light emitting layer 172, an end of the common electrode 173, an end of the first encapsulation inorganic film TFE1, an end of the second encapsulation inorganic film TFE3, an end of the second buffer film BF2, an end of the first sensor insulating film TINS1, and an end of the second sensor insulating film TINS2 may be adjacent to a boundary between the barrier dam area BDA and the first removal area ABA1 except for portions removed in the second removal area ABA2.

However, the present disclosure is not limited thereto, and an end of the light emitting layer 172, an end of the common electrode 173, an end of the first encapsulation inorganic film TFE1, an end of the second encapsulation inorganic film TFE3, an end of the second buffer film BF2, an end of the first sensor insulating film TINS1, and an end of the second sensor insulating film had NS2 may be adjacent to a boundary between the hole dam area HDA and the second removal area ABA2. In this case, a barrier dam BDAM to be described later may not include a fifth sub-barrier dam BDA5.

As illustrated in FIG. 8, the light emitting layer 172 and the common electrode 173 are disconnected in each of the first to third grooves GR1, GR2, and GR3 formed by the first to eighth tips T1 to T8, and it is thus possible to limit and/or prevent the light emitting layer 172 and the common electrode 173 exposed to the through hole TH from becoming a path through which oxygen, moisture, or the like, permeates.

The first removal area ABA1 may be disposed between the barrier dam area BDA and the cutting area CA. The first removal area ABA1 may be an area where the display layer DISL, the light emitting element layer EML, the encapsulation layer ENC, and the sensor electrode layer SENL disposed on the substrate SUB are removed. In the first removal area ABA1, the display layer DISL, the light emitting element layer EML, the encapsulation layer ENC, and the sensor electrode layer SENL may be removed to expose an upper surface of the substrate SUB. For example, the first removal area ABA1 may be an area where the first buffer film BF1, the light emitting layer 172, the common electrode 173, the first encapsulation inorganic film TFE1, the second encapsulation inorganic film TFE3, the second buffer film BF2, the first sensor insulating film TINS1, and the second sensor insulating film TINS2 are removed. In an embodiment, a width of the first removal area ABA1 in the first direction (X-axis direction) may be approximately 50 μm to 200 μm.

The barrier dam area BDA may be located between the first removal area ABA1 and the second removal area ABA2. The barrier dam area BDA may be an area where the display layer DISL, the light emitting element layer EML, the encapsulation layer ENC, and the sensor electrode layer SENL disposed on the substrate SUB remain without being removed, unlike the first removal area ABA1 and the second removal area ABA2. In an embodiment, a width of the barrier dam area BDA in the first direction (X-axis direction) may be approximately 50 μm to 150 μm.

A barrier dam BDAM may be disposed in the barrier dam area BDA. The barrier dam BDAM may limit and/or prevent an etchant from permeating into the light emitting element layer EML in an etching process of a method S1 (see FIG. 9) for manufacturing a display device to be described later. In addition, the barrier dam BDAM may limit and/or prevent the planarization film SIP from overflowing into the through hole TH.

The planarization film SIP may be disposed across the hole dam area HDA and the second removal area ABA2. The planarization film SIP may be located on a side opposite to the transmissive area TA (or the through hole TH) based on the barrier dam BDAM. The planarization film SIP may limit and/or prevent film lifting in an acid-resistant film detachment process of a method S1 (see FIG. 9) for manufacturing a display device to be described later.

The planarization film SIP may be disposed not only on an upper surface of the second sensor insulating film TINS2, but also in a valley formed by the barrier dam BDAM, the second hole dam HDAM2, and the like. For example, the valley may be formed between the barrier dam BDAM and the second hole dam HDAM2 by the second removal area ABA2. The planarization film SIP may also be disposed in the valley.

The planarization film SIP may completely seal ends of the thin film transistor layer TFTL, the light emitting element layer EML, the encapsulation layer ENC, and the sensor electrode layer SENL disposed in the hole dam area HDA. For example, the planarization film SIP may completely cover the thin film transistor layer TFTL, the light emitting element layer EML, the encapsulation layer ENC, and the sensor electrode layer SENL disposed inside the barrier dam BDAM.

The barrier dam BDAM may include a first sub-barrier dam BDA1, a second sub-barrier dam BDA2, a third sub-barrier dam BDA3, a fourth sub-barrier dam BDA4, and a fifth sub-barrier dam BDA5. The first sub-barrier dam BDA1 may be disposed on the first buffer film BF1 and may include the same material as the first organic film 160. The second sub-barrier dam BDA2 may be disposed on the first sub-barrier dam BDA1 and may include the same material as the second organic film 180. The third sub-barrier dam BDA3 may be disposed on the second sub-barrier dam BDA2 and may include the same material as the pixel defining film 190. The fourth sub-barrier dam BDA4 may be disposed on the third sub-barrier dam BDA3 and may include the same material as the spacer 191. The fifth sub-barrier dam BDA5 may be disposed on the fourth sub-barrier dam BDA4 and may include the light emitting layer 172, the common electrode 173, the first encapsulation inorganic film TFE1, the second encapsulation inorganic film TFE3, the second buffer film BF2, the first sensor insulating film TINS1, and the second sensor insulating film TINS2. However, the present disclosure is not limited thereto, and the fifth sub-barrier dam BDA5 may not include at least one of the light emitting layer 172, the common electrode 173, the first encapsulation inorganic film TFE1, the second encapsulation inorganic film TFE3, the second buffer film BF2, the first sensor insulating film TINS1, and the second sensor insulating film TINS2 or the fifth sub-barrier dam BDA5 itself may be omitted.

It has been illustrated in FIG. 8 that the barrier dam BDAM includes five sub-barrier dams, but the present disclosure is not limited thereto. The number of sub-barrier dams included in the barrier dam BDAM may be changed depending on a required height of the barrier dam BDAM.

The second removal area ABA2 may be disposed between the hole dam area HDA and the barrier dam area BDA. The second removal area ABA2 may be an area where the display layer DISL, the light emitting element layer EML, the encapsulation layer ENC, and the sensor electrode layer SENL disposed on the substrate SUB are removed. In the second removal area ABA2, the display layer DISL, the light emitting element layer EML, the encapsulation layer ENC, and the sensor electrode layer SENL may be removed to expose the upper surface of the substrate SUB. For example, the second removal area ABA2 may be an area where the first buffer film BF1, the light emitting layer 172, the common electrode 173, the first encapsulation inorganic film TFE1, the second encapsulation inorganic film TFE3, the second buffer film BF2, the first sensor insulating film TINS1, and the second sensor insulating film TINS2 are removed. In an embodiment, a width of the second removal area ABA2 in the first direction (X-axis direction) may be approximately 50 μm to 150 μm.

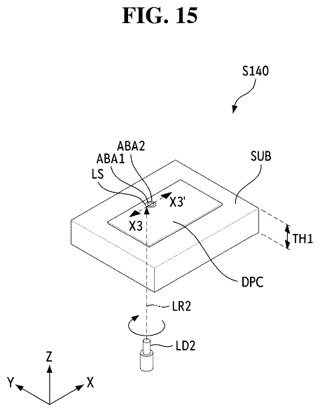

The cutting area CA may be an area where a sketch line LS (see FIG. 15) is formed in a laser sketch process of a method S1 (see FIG. 9) for manufacturing a display device to be described later. A width of the cutting area CA may be set in consideration of a width of the sketch line LS (see FIG. 15) and an etching amount. In an embodiment, a width of the cutting area CA in the first direction (X-axis direction) may be approximately 50 μm to 100 μm.

An edge TEG of the through hole TH may be disposed in the cutting area CA. The edge TEG of the through hole TH may have a shape in which it is convex toward the through hole TH. The shape of the edge TEG of the through hole TH may correspond to a shape of the sketch line LS (see FIG. 15) of a method S1 (see FIG. 9) for manufacturing a display device to be described later.

The display device 10 according to the present embodiment may have improved durability by including the planarization film SIP disposed across the display area DA and the hole non-display area HNDA and the barrier dam BDAM disposed in the hole non-display area HNDA. For example, the planarization film SIP and the barrier dam BDAM may limit and/or prevent an etchant from permeating into the light emitting element layer EML in an etching process of a method S1 (see FIG. 9) for manufacturing a display device to be described later, and may limit and/or prevent film lifting in an acid-resistant film detachment process of a method S1 (see FIG. 9) for manufacturing a display device to be described later. This will be described together with a method for manufacturing a display device according to an embodiment with reference to FIG. 9 and the like.

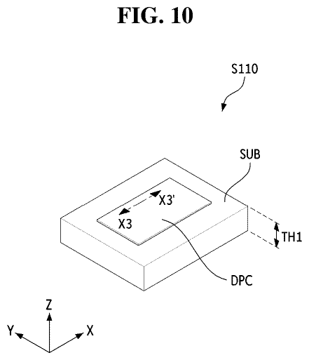

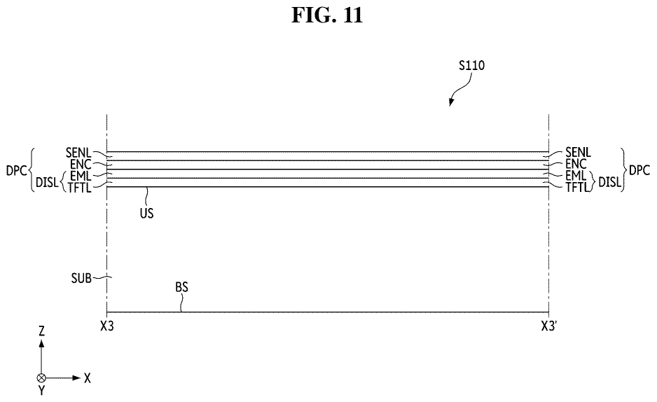

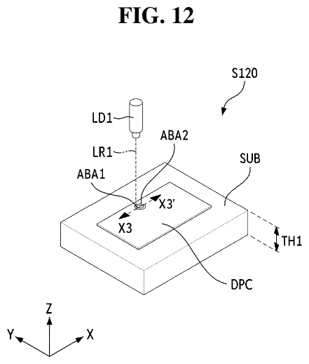

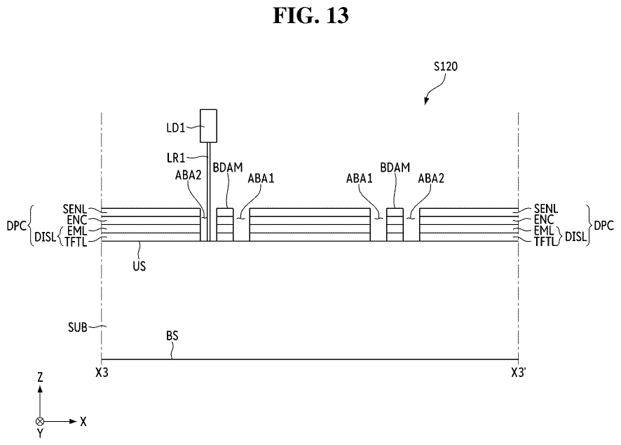

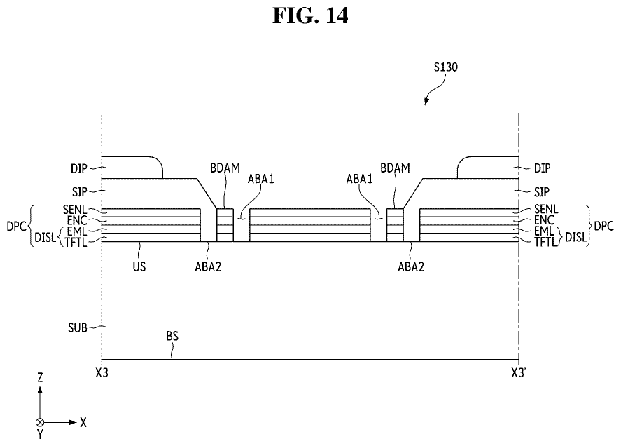

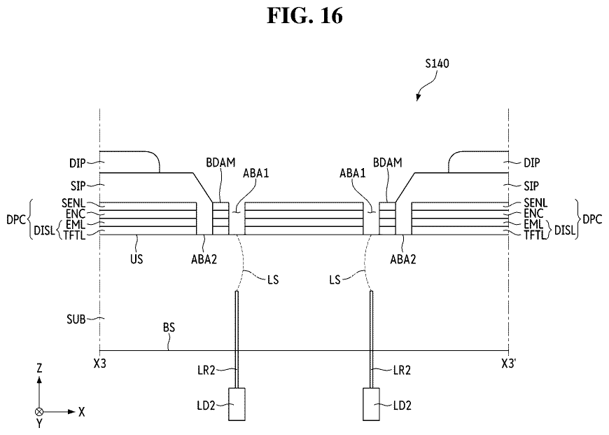

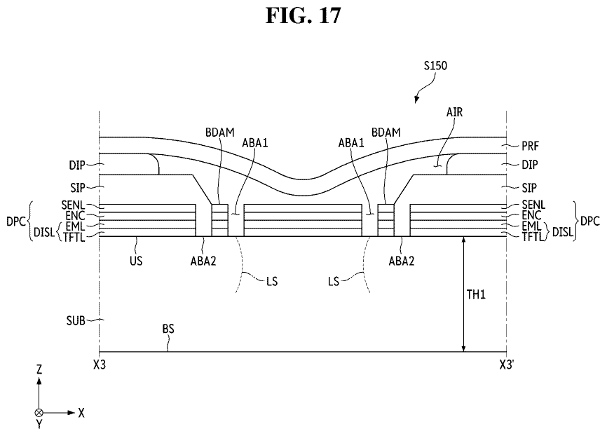

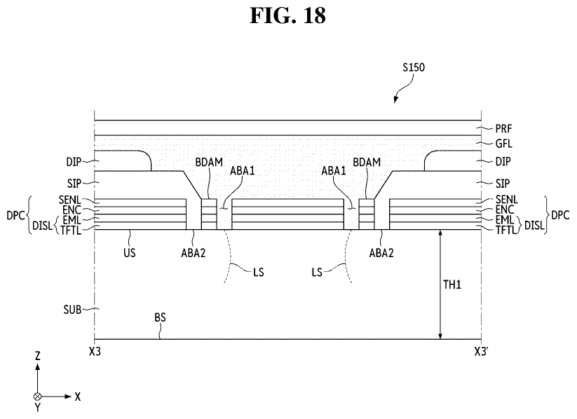

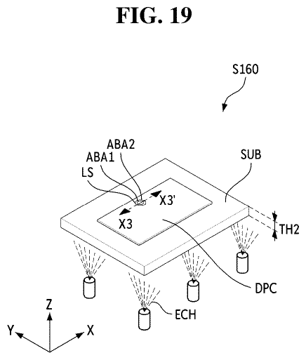

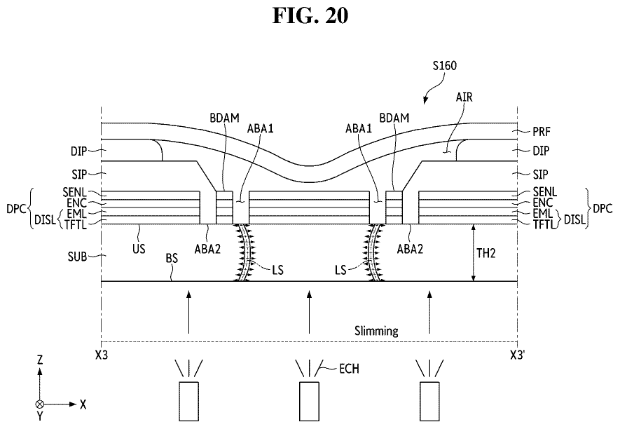

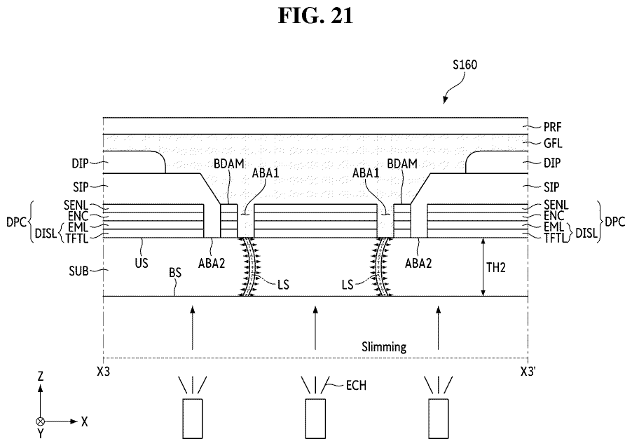

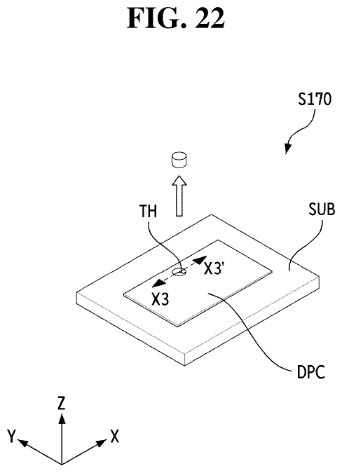

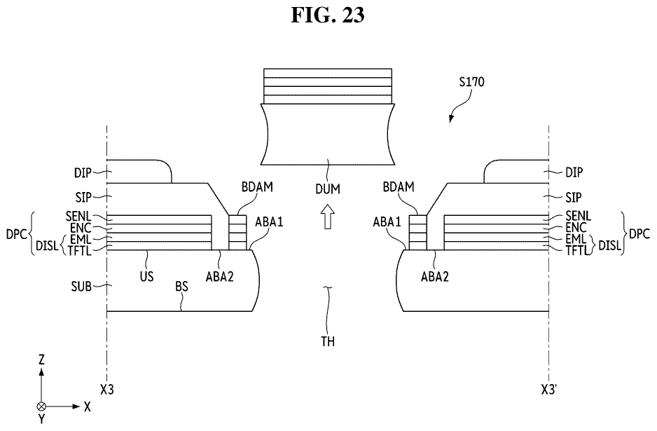

FIG. 9 is a flowchart illustrating a method for manufacturing a display device according to an embodiment. FIG. 10 is a perspective view illustrating S110 of FIG. 9. FIG. 11 is a cross-sectional view illustrating S110 of FIG. 9. FIG. 12 is a perspective view illustrating S120 of FIG. 9. FIG. 13 is a cross-sectional view illustrating S120 of FIG. 9. FIG. 14 is a cross-sectional view illustrating S130 of FIG. 9. FIG. 15 is a perspective view illustrating S140 of FIG. 9. FIG. 16 is a cross-sectional view illustrating S140 of FIG. 9. FIG. 17 is a cross-sectional view illustrating an example of S150 of FIG. 9. FIG. 18 is a cross-sectional view illustrating another example of S150 of FIG. 9. FIG. 19 is a perspective view illustrating S160 of FIG. 9. FIG. 20 is a cross-sectional view illustrating an example of S160 of FIG. 9. FIG. 21 is a cross-sectional view illustrating another example of S160 of FIG. 9. FIG. 22 is a perspective view illustrating S170 of FIG. 9. FIG. 23 is a cross-sectional view illustrating S170 of FIG. 9.

Referring to FIGS. 9 to 23, a method S1 for manufacturing a display device according to an embodiment may include forming a display cell on a first surface of a substrate (S110), forming a first removal area and a second removal area by irradiating the display cell on the first surface of the substrate with a first laser to remove a portion of the display cell (S120), forming a planarization film and a protective film on the display cell (S130), forming a sketch line for forming a through hole penetrating through a portion of the substrate by irradiating a second surface of the substrate with a second laser (S140), attaching an acid-resistant film onto the substrate, the display cell, and the planarization film (S150), reducing a thickness of the substrate and cutting the substrate along the sketch line by jetting an etchant onto the second surface of the substrate (S160), and forming the through hole by removing the acid-resistant film and a dummy (S170).

First, as illustrated in FIGS. 10 and 11, a display cell DPC may be formed on a first surface US of a substrate SUB (S110 of FIG. 9).

The display cell DPC may be located inside an edge of the substrate SUB. For example, in plan view, an edge of the display cell DPC may be surrounded by the edge of the substrate SUB.

The display cell DPC may include a display layer DISL, an encapsulation layer ENC, and a sensor electrode layer SENL, which may be stacked on top of each other. The display layer DISL may include a thin film transistor layer TFTL and a light emitting element layer EML.

Next, as illustrated in FIGS. 12 and 13, a first removal area ABA1 and a second removal area ABA2 may be formed by irradiating the display cell DPC on the first surface US of the substrate SUB with a first laser LR1 to remove a portion of the display cell DPC (S120 of FIG. 9).

Specifically, a first laser device LD1 may irradiate the display cell DPC on the first surface US of the substrate SUB with the first laser LR1. The first laser LR1 may be a femtosecond laser, but is not limited thereto. Layers removed by the first laser LR1 in the display cell DPC may be the light emitting layer 172, the common electrode 173, the first encapsulation inorganic film TFE1, the second encapsulation inorganic film TFE3, the second buffer film BF2, the first sensor insulating film TINS1, and the second sensor insulating film TINS2, as described above with reference to FIG. 8.

Such a process of removing a portion of the display cell DPC by the first laser LR1 may be referred to as a pre-ablation process.

The first removal area ABA1, a barrier dam BDAM, and the second removal area ABA2 may be formed by removing a portion of the display cell DPC. The first removal area ABA1, the barrier dam BDAM, and the second removal area ABA2 may be bilaterally symmetrical based on the through hole TH after a process is completed, but is not limited thereto.

The portion of the display cell removed during the forming the first removal area ABA1 and the second removal area ABA2 may include a first portion of the display cell DPC to define the first removal area ABA1 and a second portion of the display cell DPC to define the second removal area ABA2, A third portion of the display cell DPC may be not removed during the forming the first removal area ABA1 and the second removal area ABA2. The third portion of the display cell DPC may be between the first portion and the second portion. The third portion of the display cell DPC may form the barrier dam BDAM.

Next, as illustrated in FIG. 14, a planarization film SIP and a protective film DIP may be formed on the display cell DPC (S130 of FIG. 9).

The planarization film SIP may be a single film or multiple films made of an organic material. For example, the planarization film SIP may be formed as an organic film made of an acrylic resin, an epoxy resin, a phenolic resin, a polyamide resin, a polyimide resin, or the like. In some embodiments, the planarization film SIP may include an acrylic organic material.

The planarization film SIP may be formed by applying a liquid organic material onto the display cell DPC and the second removal area ABA2 and then curing the liquid organic material. The liquid organic material for forming the planarization film SIP may be applied by an inkjet printing process.

The planarization film SIP may not only be disposed on an upper surface of the display cell DPC, but may also fill a valley formed in the second removal area ABA2. For example, the valley may be formed between the barrier dam BDAM and the display cell DPC by the second removal area ABA2. The planarization film SIP may also be disposed in the valley. Accordingly, the display cell DPC located inside the barrier dam BDAM may be completely sealed by the planarization film SIP. For this reason, the display cell DPC is not in direct contact with an acid-resistant film PRF and a filling member GFL to be described later, and it is thus possible to limit and/or prevent an end of the display cell DPC from being lifted when the acid-resistant film PRF and the filling member GFL are detached. In addition, it is possible to limit and/or prevent an etchant from permeating toward the display cell DPC in an etching process to be described later.

The protective film DIP may be a single film or multiple films made of an organic material. For example, the protective film DIP may be formed as an organic film made of an acrylic resin, an epoxy resin, a phenolic resin, a polyamide resin, a polyimide resin, or the like. In some embodiments, the protective film DIP may include an acrylic organic material.

The protective film DIP may be formed by applying a liquid organic material onto the planarization film SIP and then curing the liquid organic material. The liquid organic material for forming the protective film DIP may be applied by an inkjet printing process.

The protective film DIP may be a protective film for protecting the display cell DPC during a manufacturing process of the display device 10. The protective film DIP may be removed in a module process after a cell process is completed during the manufacturing process of the display device 10. For example, the protective film DIP may be removed before a polarizing film PF is attached to the display cell DPC in the module process.

Next, as illustrated in FIGS. 15 and 16, a sketch line LS for forming a through hole TH penetrating through a portion of the substrate SUB may be formed by irradiating a second surface BS of the substrate SUB with the second laser LR2 (S140 of FIG. 9).

Specifically, a second laser device LD2 may irradiate the display cell DPC on the second surface BS of the substrate SUB with the second laser LR2. Various lasers may be used as the second laser LR2, but it has been described by way of example in the present disclosure that the second laser LR2 is an infrared Bessel beam having a wavelength of approximately 1030 nm.

The sketch line LS may be formed by irradiating the second laser LR2 along an edge of the through hole TH. A shape of the sketch line LS may depend on a shape of the through hole TH. For example, when the through hole TH has a circular shape in plan view, the sketch line LS may be formed in a circular shape. However, the shape of the through hole TH is not limited to the circular shape, and may be variously modified.

The sketch line LS may overlap the first removal area ABA1 in the third direction (Z-axis direction). As the sketch line LS and the first removal area ABA1 are connected to each other, the substrate SUB and a dummy DUM to be described later may be naturally separated from each other after an etching process.

In some embodiments, the sketch line LS may have a curved shape in cross section. For example, in cross section taken along the third direction (Z-axis direction), the sketch line LS may have a curved shape in which it is convex in a direction toward the through hole TH (or in a direction in which the through hole TH is to be located).

Such a process of forming the sketch line by the second laser LR2 may be referred to as a laser-sketch process.

Next, as illustrated in FIGS. 17 and 18, an acid-resistant film PRF may be attached onto the substrate SUB, the display cell DPC, and the planarization film SIP (S150 of FIG. 9).

The acid-resistant film PRF may be attached onto the substrate SUB, the display cell DPC, and the planarization film SIP that are exposed without being covered by the protective film DIP. The acid-resistant film PRF may be an acid-resistant film for protecting a plurality of display cells DPC from an etchant ECH in an etching process of the substrate SUB to be performed in the next step.

In an embodiment, as illustrated in FIG. 17, when the acid-resistant film PRF is directly attached onto the protective film DIP, an air layer AIR may be formed between the acid-resistant film PRF and the substrate SUB, the display cell DPC, and the planarization film SIP due to a step by the respective layers.

Even though the air layer AIR is formed between the acid-resistant film PRF and the substrate SUB, the display cell DPC, and the planarization film SIP as described above, such that the acid-resistant film PRF is not completely closely adhered to the display cell DPC, the planarization film SIP and the barrier dam BDAM may limit and/or prevent the permeation of the etchant into the display cell DPC.

In another embodiment, as illustrated in FIG. 18, a filling member GFL may be further disposed below the acid-resistant film PRF. The filling member GFL may be disposed on the substrate SUB, the display cell DPC, the planarization film SIP, and the protective film DIP. The filling member GFL may planarize a step by the respective layer and may further limit and/or prevent the permeation of the etchant into the display cell DPC. In some embodiments, the filling member GFL may include an acrylic organic material, but is not limited thereto.

However, when the planarization film SIP is not disposed, the filling member GFL is in direct contact with the display cell DPC, such that a phenomenon in which the end of the display cell DPC is lifted in a detachment process of the filling member GFL may occur.

In the display device 10 according to the present embodiment, the planarization film SIP may be disposed on the second removal area ABA2 and the display cell DPC to completely encapsulate the display cell DPC, and may thus limit and/or prevent the filling member GFL and the display cell DPC from being in direct contact with each other. In other words, the portions of the display cell DPC that are covered by the planarization film may not directly contact the filling member GFL. Accordingly, the phenomenon in which the end of the display cell DPC is lifted in the detachment process of the filling member GFL may be limited and/or prevented. In FIG. 18, the filling member GFL may contact the barrier dam BDAM and the portion of display cell DPC that is removed with the dummy DUM in FIG. 23.

Next, as illustrated in FIGS. 19 to 21, a thickness of the substrate SUB may be reduced and the substrate SUB may be cut along the sketch line LS, by jetting an etchant ECH onto the second surface BS of the substrate SUB (S160 of FIG. 9).

When the etchant is jetted onto the second surface BS of the substrate SUB, the thickness of the substrate SUB may be reduced from a first thickness TH1 to a second thickness TH2. Since the substrate SUB is etched without a separate mask, isotropic etching in which the entire area of the second surface BS of the substrate SUB is uniformly etched may be performed.

The sketch line LS may include a physical hole that is formed by the second laser LR2 and an area that is a surrounding area of the physical hole and has physical properties changed by a laser. Alternatively, the sketch line LS may be an area having physical properties changed by the second laser LR2 without a physical hole. For this reason, an etching rate in an area adjacent to the sketch line LS may be higher than an etching rate in other areas of the substrate SUB where the sketch line LS is not formed.

As the etchant ECH permeates into the sketch line LS, the substrate SUB may be separated along the sketch line LS. That is, a dummy DUM of a portion where the through hole TH is to be formed may be separated from the substrate SUB.

The display device 10 according to the present embodiment may limit and/or prevent the etchant ECH from permeating into the display cell DPC by including the barrier dam BDAM and the planarization film SIP disposed in the valley of the second removal area ABA2, as described above.

Next, as illustrated in FIGS. 22 and 23, the through hole TH may be formed by removing the acid-resistant film PRF and the dummy DUM (S170 of FIG. 9).

Specifically, after the etching process is completed, the acid-resistant film PRF may be detached. When the acid-resistant film PRF is detached, the filling member GFL may be removed together. In the display device 10 according to the present embodiment, as described above, the planarization film SIP may be disposed in the valley of the second removal area ABA2 to completely seal the end of the display cell DPC, and may thus limit and/or prevent the filling member GFL and the display cell DPC from being in direct contact with each other to limit and/or prevent the display cell DPC from being lifted when the filling member GFL is detached.

Thereafter, as illustrated in FIG. 23, the dummy DUM may be removed separately, but is not limited thereto. For example, the dummy DUM may be removed together with the acid-resistant film PRF and the filling member GFL by adhesive strength of the acid-resistant film PRF and the filling member GFL.

The display device 10 according to the above-described embodiment may be applied to various electronic devices 1. The electronic device 1 according to an embodiment may include the display device 10 described above, and may further include a module or a device having an additional function in addition to the display device 10.

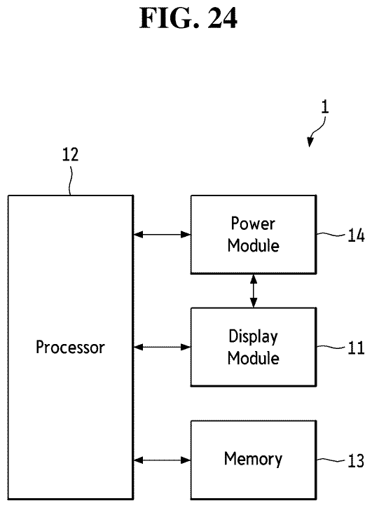

FIG. 24 is a block diagram of an electronic device according to an embodiment.

Referring to FIG. 24, an electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information used for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter (e.g., transformer circuit) or a battery and a power conversion module (e.g., power circuitry) for converting power supplied by the power supply module to generate power for one or more operation of the electronic device 1.

At least one of the respective components of the above-described electronic device 1 may be included in the display device 10 according to the above-described embodiments. In addition, some of individual modules functionally included in one module may be included in the display device 10, and the others of the individual modules may be provided separately from the display device 10. For example, the display device 10 may include the display module 11, and the processor 12, the memory 13, and the power module 14 may be provided in the form of other devices within the electronic device 1 rather than the display device 10.

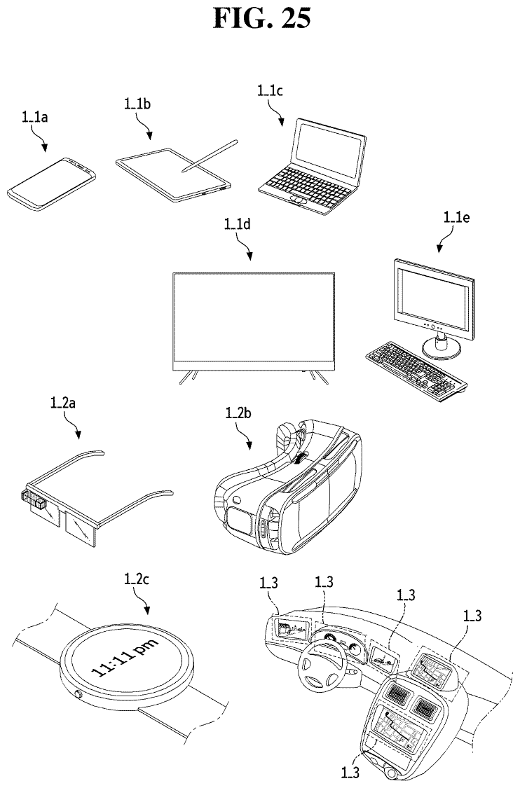

FIG. 25 is schematic views of electronic devices according to various embodiments.

Referring to FIG. 25, various electronic devices 1 to which the display device 10 according to embodiments is applied may include not only image display electronic devices 1 such as a smartphone 1_1a, a tablet PC 1_1b, a laptop computer 1_1c, a television (TV) 1_1d, and a monitor 1_1e for a desktop computer, but also wearable electronic devices 1 including display modules, such as a smart glasses 1_2a, a head mounted display 1_2b, and a smart watch 1_2c, and vehicle electronic devices 1_3 including display modules, such as a center information display (CID) disposed on an instrument board, a center fascia, or a dashboard of a vehicle and a room mirror display.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In concluding the detailed description, those skilled in the art will appreciate that many variations and modifications can be made to example embodiments without substantially departing from the principles of the present disclosure. Therefore, the disclosed example embodiments are to be used in a generic and descriptive sense only and not for purposes of limitation.

What is claimed is:

1. A display device comprising:
a substrate including a through hole and a display area surrounding the through hole;
a display layer including a thin film transistor layer on the substrate, a light emitting element layer on the thin film transistor layer, an encapsulation layer on the light emitting element layer, and a sensor electrode layer on the encapsulation layer;
a planarization film on the display layer; and
a barrier dam between the display layer and the through hole, wherein
the planarization film is on an upper portion of the display layer and inside a valley between a side portion of the display layer and the barrier dam.

2. The display device of claim 1, wherein the planarization film completely covers the upper portion of the display layer and the side portion of the display layer.

3. The display device of claim 1, wherein
the substrate further includes a first removal area between the through hole and the barrier dam, and
the display layer is not disposed on the first removal area.

4. The display device of claim 3, wherein
the substrate further includes a cutting area between the first removal area and the through hole, and
an edge of the through hole is in the cutting area, and
the edge of the through hole is defined by the substrate and has a convex shape toward the through hole.

5. The display device of claim 1, wherein
the substrate further includes a second removal area between the barrier dam and the display layer, and
the display layer is not on the second removal area.

6. The display device of claim 5, wherein the valley is in the second removal area.

7. The display device of claim 1, wherein
the thin film transistor layer includes at least one transistor and at least one organic insulating film on the at least one transistor,
the barrier dam includes a first sub-barrier dam on the substrate, and
the first sub-barrier dam includes a same material as a material in the at least one organic insulating film.

8. The display device of claim 7, wherein
the light emitting element layer includes a plurality of light emitting elements and a pixel defining film,
the plurality of light emitting elements are configured to be driven by the at least one transistor,
the pixel defining film partitions the plurality of light emitting elements,
the barrier dam further includes a second sub-barrier dam on the first sub-barrier dam, and
a material of the second sub-barrier dam is same as a material of the pixel defining film.

9. The display device of claim 8, wherein
the plurality of light emitting elements are connected to each other by a common electrode,
the plurality of light emitting elements each include a pixel electrode, a light emitting layer, and a portion of the common electrode,
the encapsulation layer includes at least one inorganic encapsulation film,
the sensor electrode layer includes at least one sensor electrode and an inorganic film covering the at least one sensor electrode,
the barrier dam further includes a third sub-barrier dam on the second sub-barrier dam, and
the third sub-barrier dam includes at least one of the light emitting layer, the common electrode, the at least one inorganic encapsulation film, and the inorganic film.

10. The display device of claim 1, wherein the planarization film includes an acrylic organic material.

11. A method for manufacturing a display device, comprising:
forming a display cell on a first surface of a substrate;
forming a first removal area and a second removal area in the display cell by irradiating the display cell with a first laser to remove a portion of the display cell;
forming a planarization film and a protective film on the display cell;
forming a sketch line for forming a through hole penetrating through the substrate by irradiating the substrate with a second laser;
attaching an acid-resistant film onto the planarization film;
reducing a thickness of the substrate and cutting the substrate along the sketch line by jetting an etchant onto a second surface of the substrate, wherein the second surface of the substrate is opposite the first surface of the substrate; and
forming the through hole by removing the acid-resistant film and a dummy, wherein
the dummy corresponds to a region of the substrate and a region of the display cell that are removed during the forming the through hole,
the first removal area is closer to the through hole compared to a distance between the through hole and the second removal area, and
a portion of the planarization film is on the second removal area.

12. The method of claim 11, wherein
the portion of the display cell removed during the forming the first removal area and the second removal area includes a first portion of the display cell to define the first removal area and a second portion of the display cell to define the second removal area,
a third portion of the display cell is not removed during the forming the first removal area and the second removal area,
the third portion of the display cell is between the first portion and the second portion,
the third portion of the display cell forms a barrier dam such that when the first portion of the display cell and the second portion of the display cell are removed by irradiating the display cell with the first laser, the third portion of display corresponding to the barrier dam remains between the first removal area and the second removal area.

13. The method of claim 12, wherein the barrier dam is between the planarization film and the through hole.

14. The method of claim 11, wherein
during the forming the sketch line, the sketch line is formed in a location of the substrate overlapping the first removal area.

15. The method of claim 11, wherein
during the forming the planarization film and the protective film on the display cell, the planarization film is formed to completely cover an upper portion of a remaining portion of the display cell and a side portion of the remaining portion of the display cell, wherein the remaining portion of the display cell is not enclosed by the second removal area.

16. The method of claim 11, further comprising:
forming a filling member between the acid-resistant film and the planarization film.

17. The method of claim 16, wherein,
when the filling member is formed, the planarization film covers an upper surface of a remaining portion of the display cell and a side surface of the remaining portion of the display cell such that the filling member is not in direct contact with the remaining portion of the display cell,
the portion of the display cell removed during the forming the first removal area and the second removal area includes a first portion of the display cell to define the first removal area and a second portion of the display cell to define the second removal area,
a third portion of the display cell is between the first removal area and the second removal area and defines a barrier dam,
the remaining portion of the display cell is separate from the third portion of the display cell and the region of the display cell that is removed during the forming the through hole.

18. The method of claim 11, wherein
after the forming the through hole, the through hole is surrounded by the first removal area and the second removal area in plan view.

19. The method of claim 11, wherein the planarization film and the protective film each include an acrylic organic material.

20. An electronic device comprising:
a display device configured to display an image;
a processor configured to provide an image driving signal to the display device; and
a power module configured to supply power to the display device and the processor, wherein
the display device includes
a substrate including a through hole and a display area surrounding the through hole,
a display layer including a thin film transistor layer on the substrate, a light emitting element layer on the thin film transistor layer, an encapsulation layer on the light emitting element layer, and a sensor electrode layer on the encapsulation layer,
a planarization film on the display layer, and
a barrier dam between the display layer and the through hole,
wherein the planarization film is on an upper portion of the display layer and inside a valley between a side portion of the display layer and the barrier dam.
